(19) United States
(12) Patent Application Publication
(10) Pub. No.: US 2016/0291402 A1
(43) Pub. Date: Oct. 6, 2016

(54) DISPLAY PANEL AND DISPLAY DEVICE

(71) Applicant: BOE TECHNOLOGY GROUP CO., LTD., Beijing (CN)

(72) Inventor: Dongfang Wang, Beijing (CN)

(73) Assignee: BOE TECHNOLOGY GROUP CO., LTD., Beijing (CN)

(21) Appl. No.: 14/891,072

(22) PCT Filed: Apr. 16, 2015
(86) PCT No.: PCT/CN2015/076772

§ 371 Date: Nov. 13, 2015

(30) Foreign Application Priority Data
Dec. 22, 2014 (CN) 201410808287.0

(51) Int. Cl. G02F 1/1335; H01L 27/32; G02F 1/1362

(52) U.S. Cl. CPC G02F 1/133514; G02F 1/136209; G02F 1/136286; H01L 27/3244; H01L 27/322; G02F 2001/136222

(57) ABSTRACT

A display panel and a display device are provided. The display panel includes a plurality of scanning signal lines (3), a plurality of data signal lines (4), a crisscrossed black matrix (21), and a color filter (22) with at least three different colors; the scanning signal lines (3) and the data signal lines (4) intersect with each other to form a plurality of sub-pixels (5); the black matrix (21) divides the color filter (22) into a plurality of color sub-units (221); the display panel comprises a plurality of display units (20), each display unit (20) comprises color sub-units (221) of different colors, and at least one color sub-units (221) of the display unit (20) correspond to more than two sub-pixels (5). The display panel solves the problem that the aperture ratio of the conventional display panels is small.

### TECHNICAL FIELD

Embodiments of the present invention relate to a display panel and a display device.

### BACKGROUND

Display panels are widely used in display devices such as mobile phones, televisions, tablet computers, and the like. Currently, the display panels in the market mainly comprise liquid crystal display panels, OLED (Organic Light-Emitting Diode) display panels, electronic paper, and etc.

A display panel usually comprises an array substrate and a color filter substrate; the array substrate comprises a plurality of scanning signal lines (S1-Sn) and a plurality of data signal lines (D1-Dn), and the plurality of scanning signal lines and the plurality of data signal lines intersect with each other to form a plurality of sub-pixels. The color filter substrate comprises a color filter layer and a black matrix, the black matrix corresponds to the opaque parts of the array substrate such as the scanning signal lines and the data signal lines, and the black matrix divides the color filter layer into a plurality of color units that are in one-to-one correspondence with the pixel electrodes on the array substrate.

### SUMMARY

Embodiments of the present invention provide a display panel and a display device, the display panel has a large aperture ratio, which is favorable for displaying high quality images.

An embodiment of the present invention provides a display panel comprising a plurality of scanning signal lines, a plurality of data signal lines, a crisscrossed black matrix, and a color filter with at least three different colors; the plurality of scanning signal lines and the plurality of data signal lines intersect with each other to form a plurality of sub-pixels; the black matrix divides the color filter into a plurality of color sub-units; the display panel comprises a plurality of display units, and each display unit comprises color sub-units of different colors and at least one color sub-unit of the display unit corresponds to more than two sub-pixels.

An embodiment of the present invention also provides a display device, comprising any one of display panels according to the embodiments of the present invention.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention, those skilled in the art can obtain other drawings according to these drawings without any inventive work.

FIG. 1 is a schematic view illustrating scanning signal lines and data signal lines intersecting with each other to form sub-pixels;

FIG. 2 is a schematic view of the color filter corresponding to the sub-pixel illustrated in FIG. 1;

FIG. 3 is a schematic view of a color filter corresponding to the sub-pixel illustrated in FIG. 1 of a display panel according to an embodiment of the present invention;

FIG. 4 is a schematic view of a color filter corresponding to the sub-pixel illustrated in FIG. 1 of another display panel according to an embodiment of the present invention;

FIG. 5 is a schematic view of a color filter of another display panel according to an embodiment of the present invention;

FIG. 6 is a schematic view illustrating scanning signal lines and data signal lines on the display panel, intersecting with each other to form sub-pixels, according to an embodiment of the present invention and corresponding to FIG. 5;

FIG. 7 is a schematic view of a color filter of another display panel according to an embodiment of the present invention;

FIG. 8 is a schematic view illustrating scanning signal lines and data signal lines on the display panel, intersecting with each other to form sub-pixels, according to an embodiment of the present invention and corresponding to FIG. 7; and

FIG. 9 is a cross section schematic view of a display panel according to an embodiment of the present invention.

1: array substrate; 2: color filter substrate; 3: scanning signal line; 4: data signal line; 5: sub-pixel; 10: pixel electrode; 20: display unit; 21: black matrix; 22: color filter; 221: color sub-unit; 201: first display unit; 202: second display unit.

### DETAILED DESCRIPTION

The technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

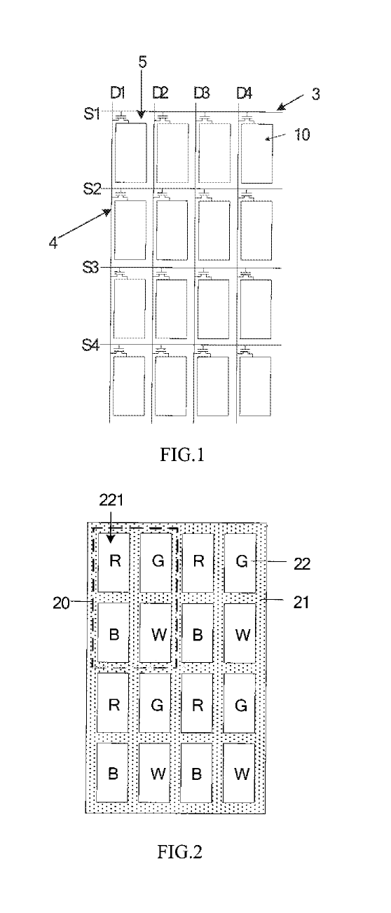

As shown in FIG. 1, the scanning signal lines S1-S4 and the data signal lines D1-D4 on the array substrate intersect with each other to form 16 sub-pixels, and each sub-pixel 5 is corresponding to a pixel electrode 10. A color filter substrate as illustrated in FIG. 2 comprises a black matrix 21 and a color filter 22, and the color filter 22 comprises four colors that are red (R), green (G), blue (B) and white (W). The black matrix 21 divides the color filter 22 into 16 color sub-units 221 that are in one-to-one correspondence with the 16 sub-pixels on the substrate illustrated in FIG. 1. The color filter substrate and the array substrate are cell-assembled together and then form 4 display units 20, and each display unit 20 comprises color sub-units 221 corresponding to the four different colors, that is, red (R), green (G), blue (B) and white (W), the color sub-units 221 of the display unit 20 is in one-to-one correspondence with the 4 sub-pixels on the array substrate.

The black matrix on the color filter substrate is disposed between two adjacent color sub-units to prevent light leakage, and the black matrix usually covers at least a part of the color filter layer; the aperture ratio of a pixel refers to the ratio of the transparent area in a display unit, other than the opaque part such as thin film transistor, to the area of the display unit. The black matrix is wide, and the aperture ratio of pixel is small accordingly. Especially for a WOLED (White Organic Light-Emitting Diode) display panel, color display is realized with a color filter substrate; in order to prevent an organic light emitting layer from being breakdown because molecules or other things between organic light emitting layers are pressed by the color filter substrate, the space between the color filter substrate and the array substrate is configured large, meanwhile in order to prevent light leakage between sub-units of different colors, the black matrix on the color filter substrate is wide, which results in a small aperture ratio of the OLED display panel so it is unfavorable to develop high resolution OLED products.

An embodiment of the present invention provides a display panel comprising a plurality of scanning signal lines, a plurality of data signal lines, and the plurality of scanning signal lines and the plurality of data signal lines intersecting with each other to form a plurality of sub-pixels; the display panel further comprises a crisscrossed black matrix and a color filter with at least three different colors, the black matrix divides the color filter into a plurality of color sub-units; the display panel comprises a plurality of display units, and each display unit comprises color sub-units of different colors and at least one color sub-units of the display unit correspond to more than two sub-pixels.

In a display panel according to an embodiment of the present invention, at least one color sub-unit of a display unit corresponds to more than two sub-pixels, thus on one hand because one color sub-unit corresponds to more than two sub-pixels, no light leakage is between the more than two sub-pixels, and on the other hand because one color sub-unit corresponds to more than two sub-pixels, a black matrix is not required to be disposed between the sub-pixels corresponding to the same color sub-unit, which can increases the aperture ratio of a pixel.

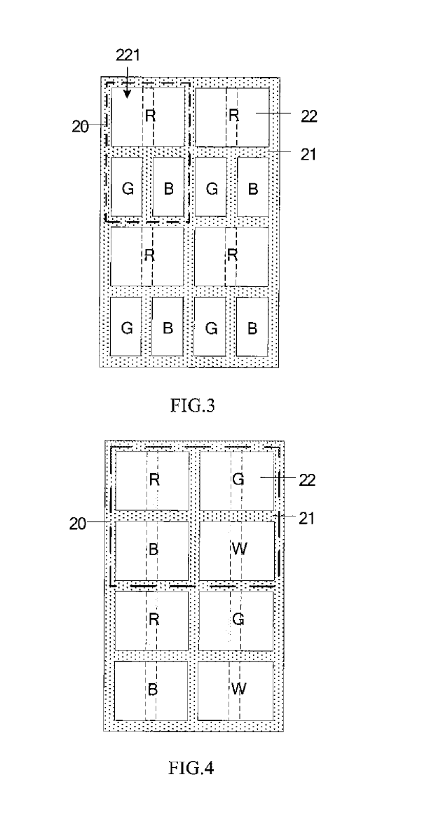

A display panel according to an embodiment of the present invention, as shown in FIG. 3, comprises a plurality of scanning signal lines 3, a plurality of data signal lines 4, a crisscrossed black matrix 21, and a color filter 22 with at least three different colors. The plurality of scanning signal lines 3 and the plurality of data signal lines 4 intersect with each other to form a plurality of sub-pixels 5; the black matrix 21 divides the color filter 22 into a plurality of color sub-units 221; the display panel comprises a plurality of display units 20, each display unit 20 comprises color sub-units 221 with different colors, and at least one color sub-units 221 of the display unit 20 correspond to more than two sub-pixels 5. The scanning signal lines 3, the data signal lines 4 and the sub-pixels 5 can be referred to FIG. 1.

The sub-pixels 5 corresponding to the color sub-units 221 of the display unit 20 comprises a sub-pixel 5 disposed in a different row or column from other sub-pixels of this display unit 20.

For example, as shown in FIG. 3, the color filter 22 can comprise three different colors, red (R), green (G) and blue (B), a color sub-unit 221 of any one of the colors in the display unit 20 corresponds to two sub-pixels, the color sub-units 221 of the other two colors each correspond to one sub-pixel. In FIG. 3, the red (R) sub-unit corresponds to two sub-pixels and the green (G) sub-unit and the blue (B) sub-unit each correspond to one sub-pixel, which is taken as an example. Thus, the display panel as shown in FIG. 3 comprises four display units, one display unit corresponds to four sub-pixels 5 as shown in FIG. 1, the four display units 20 of the color filter 22 correspond to the 16 sub-pixels as shown in FIG. 1. Because the red sub-unit corresponds to two sub-pixels, the part between the two sub-pixels still corresponds to the red sub-unit and has no black matrix therein, and this configuration not only can simplify the manufacturing process, but also can increase the aperture ratio of the two sub-pixels.

It should be noted that a color sub-unit of any one of the colors in a display unit corresponds to two sub-pixels, and color sub-units of the other colors can also correspond to two sub-pixels respectively. The embodiments and drawings of the present invention are illustrated only with the example in which a color sub-unit of any one of the colors in the display unit corresponds to two sub-pixels, and color sub-units of the other colors correspond to one sub-pixel, two or four sub-pixel respectively as an example.

For example, the color filter can comprise four different colors that are red, green, blue and white, or red, green, blue and yellow. Color sub-units of any two colors in a display unit correspond to two sub-pixels respectively, and color sub-units of the other two colors correspond to four sub-pixels respectively. For example, color sub-units of any two colors in a display unit correspond to one sub-pixel respectively, and color sub-units of the other two colors correspond to two sub-pixels respectively.

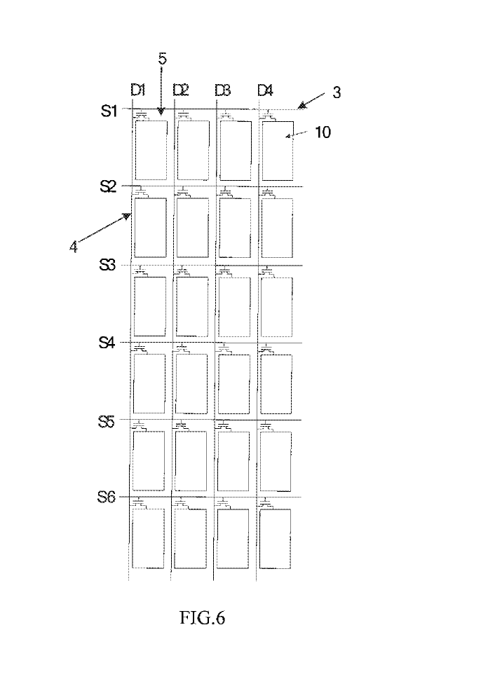

Otherwise, as shown in FIG. 5, the color filter comprises four different colors that are red (R), green (G), blue (B) and white (W), which is taken as an example. The red (R) sub-unit and the green (G) sub-unit of the first display unit 201 correspond to two sub-pixels respectively, and the blue (B) sub-unit and the white (W) sub-unit correspond to four sub-pixels respectively. The red (R) sub-unit and the green (G) sub-unit of the second display unit 202 correspond to four sub-pixels respectively, and the blue (B) sub-unit and the white (W) sub-unit correspond to two sub-pixels respectively. Taking the first display unit 201 as an example, because the red (R) sub-unit and the green (G) sub-unit correspond to two sub-pixels respectively, there is no black matrix in the part between the two sub-pixels corresponding to the red (R) sub-unit or the green (G) sub-unit, and the aperture ratio of the two sub-pixels can be increased. The blue (B) sub-unit and the white (W) sub-unit correspond to four sub-pixels respectively, and there is no black matrix in the part among the four sub-pixels corresponding to the blue (B) sub-unit or the white (W) sub-unit, and the aperture ratio of the four sub-pixels can be increased.

The display unit as shown in FIG. 5 comprises the first display unit 201 and the second display unit 202, the first display unit 201 corresponds to 12 sub-pixels, and the second display unit 202 corresponds to 12 sub-pixels. The arrangement of the sub-pixels corresponding to the color filter as shown in FIG. 5 can be shown in FIG. 6, and 24 sub-pixels are formed by the scanning signal lines S1-S6 and the data signal lines D1-D4. The display unit as shown in FIG. 5 corresponds to 12 sub-pixels, and the two display units of the color filter correspond to the 24 sub-pixels as shown in FIG. 6.

For example, each color sub-unit of the display unit can correspond to the same amount of sub-pixels.

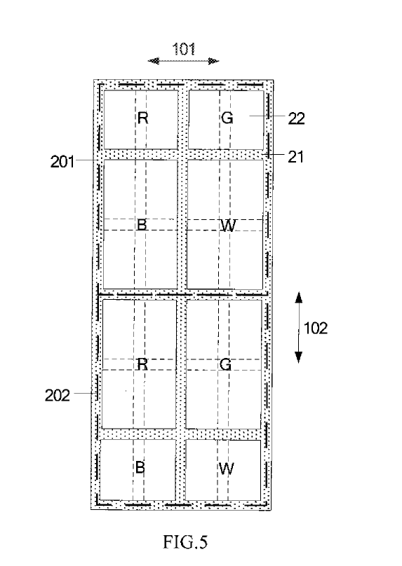

For example, as shown in FIG. 4, the blue (B) sub-unit and the white (W) sub-unit correspond to two sub-pixels respectively, i.e., each color sub-unit of the display unit 20 corresponds to the same amount of sub-pixels, which is further favorable for manufacturing. Because the red (R) sub-unit, the green (G) sub-unit, the blue (B) sub-unit and the white (W) sub-unit correspond to two sub-pixels respectively, there is no black matrix in the part between the two sub-pixels corresponding to each color sub-unit, and the aperture ratio of the two sub-pixels can be increased. The display unit as shown in FIG. 4 corresponds to eight sub-units, and the two display units of the color filter correspond to 16 sub-pixels as shown in FIG. 1.

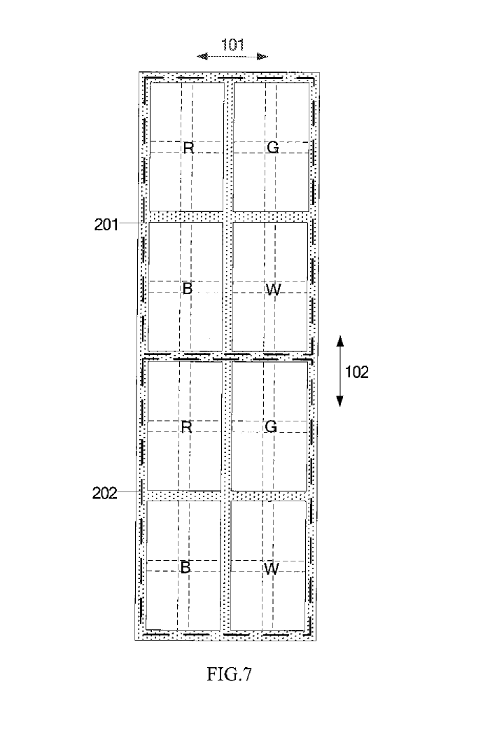

For example, as shown in FIG. 7, the color filter comprises four different colors that are red (R), green (G), blue (B) and white (W), which is taken as an example, and each color sub-unit of the first display unit 201 and the second display unit 202 corresponds to four sub-pixels respectively. Because the red (R) sub-unit, the green (G) sub-unit, the blue (B) sub-unit and the white (W) sub-unit correspond to four sub-pixels respectively, there is no black matrix in the part among the four sub-pixels corresponding to each color sub-unit, and the aperture ratio of the four sub-pixels can be increased.

In FIG. 7, the first display unit 201 and the second display unit 202 corresponds to 16 sub-pixels respectively, the arrangement of the sub-pixels corresponding to the color filter as shown in FIG. 7 can be shown in FIG. 8, and 32 sub-pixels are formed by the scanning signal lines S1-S8 and the data signal lines D1-D4. The display unit as shown in FIG. 7 corresponds to 16 sub-pixels, and the two display units of the color filter correspond to 32 sub-pixels as shown in FIG. 8.

In a display panel provided according to an embodiment of the present invention, for example, at least one color sub-unit of a display unit corresponds to more than two and less than six sub-pixels. That is, any one of the color units of one display unit can correspond to two or six sub-pixels, and of course can also correspond to three or five sub-pixels. The embodiments and drawings of the present invention are illustrated with an example in which a color sub-unit corresponds to two or four sub-pixels.

For example, the display units form a plurality of rows in the direction of the scanning signal lines or the data signal lines, and the display units in a same row are identical to each other. Because the scanning signal lines and the data signal lines intersect with each other, the display units can form a plurality of rows in the direction of the scanning signal lines; meantime the display units arranged in the direction of the data signal lines can form a plurality of columns, and the display units disposed in the same column can be same or different. Alternatively, the display units can form a plurality of columns in the direction of the data signal lines; meantime, the display units form a plurality of rows in the direction of the scanning signal lines, and the display units disposed in the same row can be same or different. The display units are identical to each other, i.e., the positions of the color sub-units of different colors in the display units are identical, and the amounts of the sub-pixels corresponding to the color sub-units of different colors are identical too. The display units are different, i.e., between the display units either the positions of the color sub-units of different colors or the amounts of the sub-pixels corresponding to the color sub-units of different colors are different.

For example, the display units in at least two rows constitute one group, and the display panel comprises a plurality of groups of display units, and the display units in the rows of same one group are different. As shown in FIG. 5, the display units form a plurality of rows in the direction of scanning signal lines (i.e., the direction 101). As shown in FIG. 5, one first display unit 201 constitutes one row and one second display unit 202 constitutes another row as an example, which is taken as an example, the first display unit 201 and the second display unit 202 form one group in the direction of the data signal lines (i.e., the direction 102), and the first display unit 201 is different from the second display unit 202.

For example, as shown in FIG. 5, the red sub-unit and the green sub-unit of the first display unit 201 correspond to two sub-pixels respectively, and the blue sub-unit and the white sub-unit correspond to four sub-pixels respectively. The red sub-unit and the green sub-unit of the second display unit 202 correspond to four sub-pixels respectively, and the blue sub-unit and the white sub-unit correspond to two sub-pixels respectively.

It should be noted that the difference between the display units in same one group can be in any other way, which is not specifically limited in the embodiment of the present invention, which only takes the above-mentioned embodiments as examples for illustration.

The display panel according to any embodiment of the present invention can be any display panel with color sub-pixels and sub-pixels such as a liquid crystal display panel, an OLED (Organic Light-Emitting Diode) display panel, and etc.

It should be noted that the display panel according to an embodiment of the present invention comprises a plurality of scanning signal lines, a plurality of data signal lines, a black matrix, and a color filter; the plurality of scanning signal lines, the plurality of data signal lines, the black matrix, and the color filter can be formed on the same substrate or on different substrates.

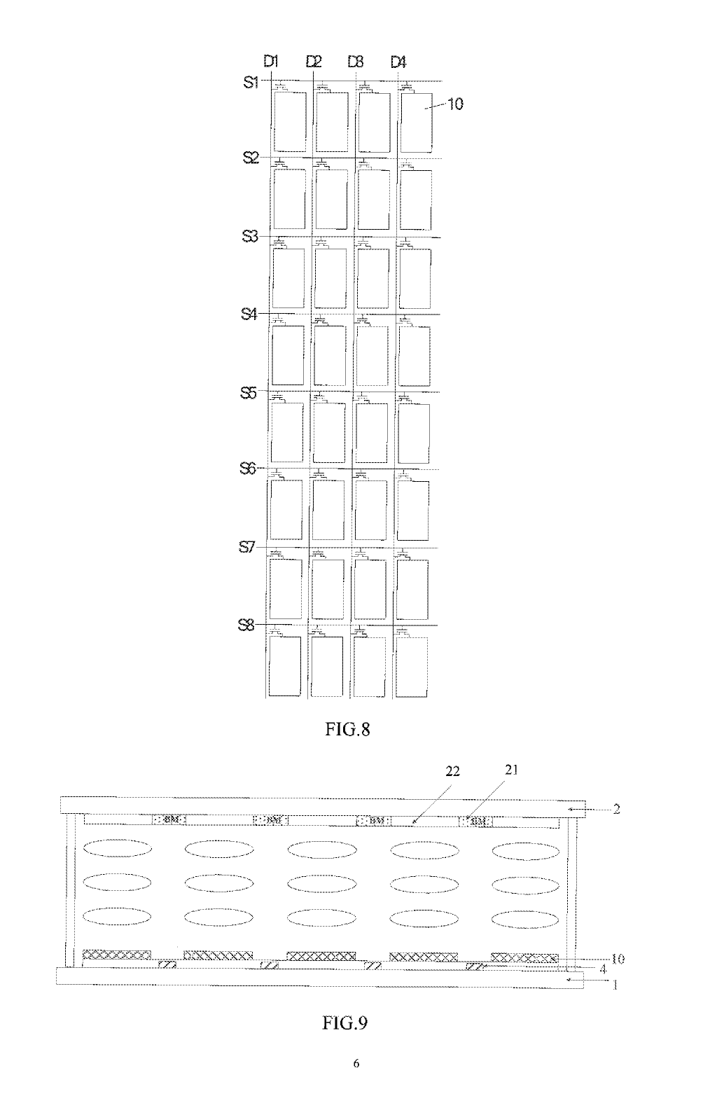

For example, the display panel according to an embodiment of the present invention comprises an array substrate 1 and a color filter substrate 2 that cell-assembled together, the scanning signal lines 3 and the data signal lines 4 are formed on the array substrate 1, and the black matrix 21 and the color filter 22 are formed on the color filter substrate 2, as shown in FIG. 9. FIG. 9 only illustrates the part related to the present application while does not illustrate other structures. For the purpose of convenience of description, the embodiments of the present invention take the display panel comprising an array substrate 1 and a color filter substrate 2 that are cell-assembled together for example for detailed description. In the display panel according to an embodiment of the present invention, the provision of the scanning signal lines and the data signal lines can be the same as the conventional technology, and therefore the drawings of the embodiments of the present invention only show the black matrix, the color filter, etc, and the provision of the scanning signal lines and the data signal lines may conducted with reference to FIG. 1.

An embodiment of the present invention also provides a display device which comprises any one of display panels according to the embodiments of the present invention. The display device can be a display device such as a liquid crystal display device, electronic paper, OLED (Organic Light-Emitting Diode) display device, and any product or component having a display function and comprising the display device, such as television, digital camera, mobile phone, watch, tablet computer, laptop computer, navigator or the like.

A display panel and a display device are provided according to the embodiments of the present invention, at least one color sub-unit of a display unit of the display panel corresponds to more than two sub-pixels; on one hand, because one color sub-unit corresponds to more than two sub-pixels, there is no light leakage between the more than two sub-pixels, and on the other hand, because one color sub-unit corresponds to the more than two sub-pixels, the black matrix between the more than two sub-pixels is eliminated, which can increase the aperture ratio of pixels.

What are described above is related to the illustrative embodiments of the disclosure only and not limitative to the scope of the disclosure, any various changes or replacement within the scope of the disclosure, which can be easily thought out by those skilled in the art, should be included within the scope of the present invention. Therefore, the scopes of the disclosure are defined by the accompanying claims.

The present application claims the priority of the Chinese Patent Application No. 201410808287.0 filed on Dec. 22, 2014, which is incorporated herein by reference as part of the disclosure of the present application.

1. A display panel, comprising a plurality of scanning signal lines, a plurality of data signal lines, a crisscrossed black matrix, and a color filter with at least three different colors, wherein the plurality of scanning signal lines and the plurality of data signal lines intersect with each other to form a plurality of sub-pixels; the black matrix divides the color filter into a plurality of color sub-units; the display panel comprises a plurality of display units, and each display unit comprises color sub-units of different colors and at least one color sub-unit of the display unit corresponds to more than two sub-pixels.

2. The display panel according to claim 1, wherein the at least one color unit corresponds to less than six sub-pixels.

3. The display panel according to claim 1, wherein the color filter comprises three different colors that are red, green and blue, one color sub-unit of any one of the colors of the display unit corresponds to two sub-pixels, and color sub-units of the other colors correspond to one sub-pixel respectively.

4. The display panel according to claim 1, wherein the color filter comprises four different colors that are red, green, blue and white or red, green, blue and yellow, color sub-units of any two colors of the display unit correspond to one sub-unit respectively, and color sub-units of the other two colors correspond to two sub-units respectively.

5. The display panel according to claim 1, wherein each color sub-unit of the display unit corresponds to a same amount of sub-pixels.

6. The display panel according to claim 5, wherein the color filter comprises four different colors that are red, green, blue and white or red, green, blue and yellow, and each color sub-unit of the display unit corresponds to two or four sub-pixels.

7. The display panel according to claim 1, wherein the display units form a plurality of rows in a direction of the scanning signal lines, or the display units form a plurality of columns in a direction of the data signal lines, and the display units disposed in a same row or in a same column are identical.

8. The display panel according to claim 7, wherein the display units disposed in at least two rows or in at least two columns form one group, the display panel comprises a plurality of groups of display units, and the display units disposed in different rows or different columns in same one group are different.

9. The display panel according to claim 1, comprising an array substrate and a color filter substrate that are cell-assembled together, wherein the scanning signal lines and the data signal lines are formed on the array substrate, and the black matrix and the color filter are formed on the color filter substrate.

10. A display device, comprising the display panel according to claim 1.

11. The display panel according to claim 1, wherein the color filter comprises three different colors that are red, green and blue, one color sub-unit of any one of the colors of the display unit corresponds to two sub-pixels, and color sub-units of the other colors correspond to one sub-pixel respectively.

12. The display panel according to claim 2, wherein the color filter comprises four different colors that are red, green, blue and white or red, green, blue and yellow, color sub-units of any two colors of the display unit correspond to one sub-unit respectively, and color sub-units of the other two colors correspond to two sub-units respectively.

13. The display panel according to claim 2, wherein each color sub-unit of the display unit corresponds to a same amount of sub-pixels.

14. The display panel according to claim 13, wherein the color filter comprises four different colors that are red, green, blue and white or red, green, blue and yellow, and each color sub-unit of the display unit corresponds to two or four sub-pixels.

15. The display panel according to claim 2, wherein the display units form a plurality of rows in a direction of the scanning signal lines, or the display units form a plurality of columns in a direction of the data signal lines, and the display units disposed in a same row or in a same column are identical.

16. The display panel according to claim 15, wherein the display units disposed in at least two rows or in at least two columns form one group, the display panel comprises a plurality of groups of display units, and the display units disposed in different rows or different columns in same one group are different.

17. The display panel according to claim 2, comprising an array substrate and a color filter substrate that are cell-assembled together, wherein the scanning signal lines and the data signal lines are formed on the array substrate, and the black matrix and the color filter are formed on the color filter substrate.
